(19) United States
(12) Patent Application Publication
(10) Pub. No.: US 2007/0221200 A1
(43) Pub. Date: Sep. 27, 2007

(54) Self powered latent heat capturing device

(76) Inventor: Richard Benson Landon, Santa Cruz, CA (US)

Correspondence Address: RICHARD LANDON, 1787 BRANCIFORTE DRIVE, SANTA CRUZ, CA, 95065, US

(21) Appl. No.: 11/389,453

(22) Filed: Mar. 27, 2006

(51) Int. Cl. F24C 1/00; F24C 15/00; F23J 13/02; H01L 35/28

(52) U.S. Cl. 126/307 R; 136/211; 126/58; 165/901

(57) ABSTRACT

An inline vent pipe insert or attachment operating to capture latent heat for living room temperature maintenance. Configured to replace or attach to an exiting vent pipe section and further configured to self-generate power to supply electric current sufficient to operate a blower. The blower configured to draw cool room air through the invention and sufficient to circulate the cool air through a further configured enclosed channel duct with sufficiently configured heat dissipation fins to capture latent heat from the inline vent. Said heat dissipation fins function as cooling heat sink for a thermal electric generator based on the Seebeck principles strategically configured to capture maximum heat from the vent pipe. The invention delivers warmed air to the room through a shroud, capturing latent heat otherwise lost to the external vent without an external power supply. The delivery of warm is configured to the rate at which latent heat is available.

### FIELD OF INVENTION

The invention as disclosed here consists of a self powered latent heat capturing device. In particular, this device could be used to produce heat for maintaining indoor living space temperatures. The device is installed in-line and integral or directly attached to a hot gas vent pipe connected to an apparatus such as a furnace, a wood stove or pellet stove.

### BACKGROUND AND SUMMARY OF INVENTION

Combustion efficiencies of typical bio-mass and fossil fuel furnace systems approach 85 percent at best with excess heat rising with hot exhaust gases through a vent pipe typically open to the atmosphere. At least fifteen percent of the heat is lost to the atmosphere.

In another typical configuration, machinery operates in many factory facilities producing hot gases with latent heat. Once again, the gases, sometimes scrubbed for pollution controls, are vented to the atmosphere. In certain circumstances, facilities piping is used to heat areas of a workplace in manufacturing buildings, thereby reducing the cost of a dedicated heating systems to that area. There may be instances where piping is configured purposefully to capture and direct latent heat to a certain living area or working area by routing extra piping through the general area before venting it up through a roof pipe or chimney to the atmosphere.

In the typical wood stove installation, the exiting vent pipe rises vertically, directly above the wood stove and extends up through an insulated roof venting area. Code requirements are very stringent concerning the area where the hot exhaust pipe from the wood stove travels through and close to the roof area. Typically, the temperature of a single wall pipe installation on a wood stove can reach temperatures is hot as 1,000° F., hottest just above the wood stove On a typical pellet stove, the inside gas vent temperatures approach 500° F. In the typical installation, the single wall pipe rises above the wood stove and proceeds to the roof flange area into a special double walled insulated pipe to protect nearby flammable materials. The single wall pipe directly above the installed wood stove, or pellet stove, in another case, provides extra heat to the living room by means of straight convection.

Convection thermal gradients are small from the top to the bottom of the pipe as the gas rises swiftly, providing the room with little net heat gain.

An objective of the invention is to capture latent heat from the vent pipe, essentially raising the efficiency of the attached heating device. Today, existing incentives provide for tax credits when homeowners remove old inefficient wood stoves and replace them with more efficient modern wood stoves certified by new EPA standards. And objective of the invention is to provide a quick and inexpensive way to increase the efficiency of such older wood stoves without replacing them.

In order to produce more efficient heat, another objective of the device is to be self powered. A typical thermal electric generator converts heat directly to electricity to run a blower sufficient to circulate cool room air through the invention. By attaching to or inserting in-line to the vent pipe, the invention efficiently captures latent heat by moving cool room air across a typical heat dissipation fin assembly as shown below.

An additional objective of the invention is to redirect the warm air back into a living or workspace.

In a further objective of the invention, latent heat is captured to operate the invention so it can be located in a convenient area without external power requirements. An embodiment of the invention is to not interfere with the flow of vent gases in order to capture latent heat. The machinery or heating apparatus need not be adjusted or modified in any way to accommodate the installation of the invention.

An additional embodiment of the present invention, configures placement and size of the invention to maintain proper and acceptable hot gas venting temperatures to minimize creosote buildup.

In yet another embodiment of the invention, it is easily attached to an existing vent pipe, using the vent pipe only to capture heat and does not interfere with present gas flow.

The invention as shown will deliver an economical solution in a time of rising cost of fossil and bio-mass fuels.

### BRIEF DESCRIPTION OF DRAWINGS

FIG. 1 is a sectional 3D illustration of the invention as an in-line sectional piece of gas vent pipe from a heating device or apparatus, venting hot gas.

FIG. 2 is a sectional 3D illustration of the invention as an attachment to a hot gas vent from an existing heating device or apparatus, venting hot gas.

### DETAILED DESCRIPTION OF THE INVENTION

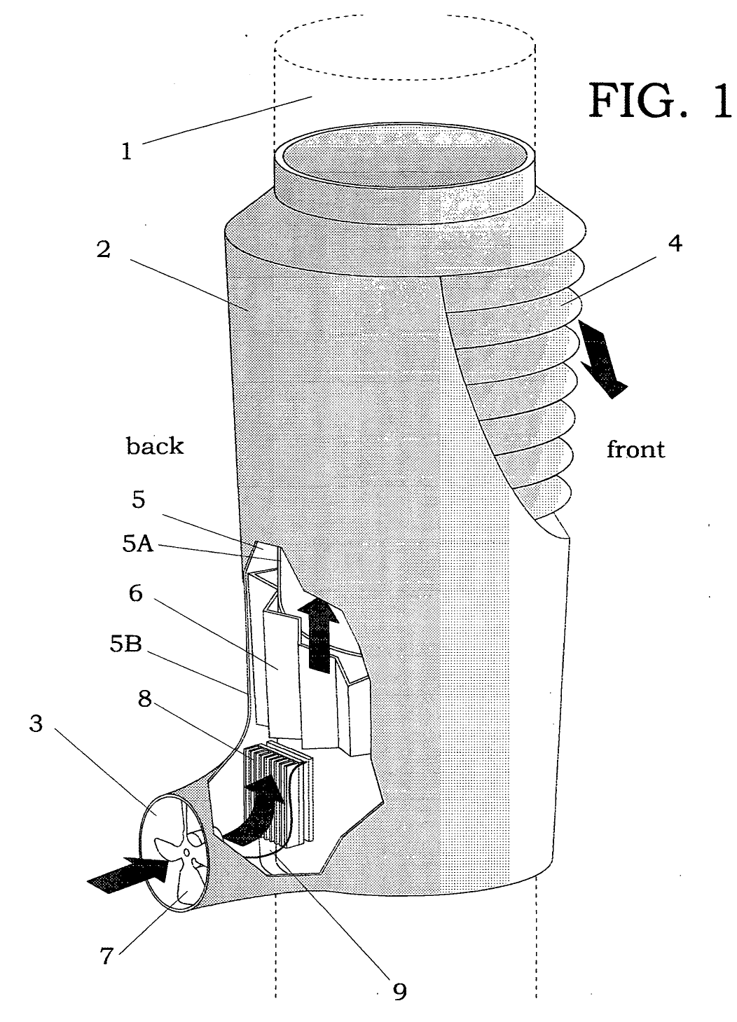

Turning to FIG. 1, there is illustrated a replacement sectional piece of stovepipe in the spirit of the invention. Referenced in the illustration, is the front and back of the invention as typically installed in a vertical stovepipe coming from the wood stove or a pellet stove. The illustration points to an existing stovepipe (1) where the invention comprises a body (2) with one end configured as a typical stovepipe male flange (2A), and the other end configured as a typical female flange (2B). In a preferred embodiment of the invention, it may replace any sectional piece of common stove pipe installation. It is envisioned that the first stovepipe section would be replaced by the invention, thereby receiving the maximum amount of heat as it first exits the stove. The inner wall continuity between the existing stovepipe and invention is uninterrupted, and the length of wall inside the invention acts to replace the sectional piece of pipe in all normal functions. Another embodiment of the invention, sizes the length of the invention to that of the standard length of stovepipe, thereby making a retrofit installation straightforward and easy.

The body is also comprised of a cool air inlet (3) and a hot air outlet (4).

In the spirit of the invention, the cool air inlet faces towards the back of a typically installed wood stove and the hot air outlet faces forwards the front in the same installation.

With reference to the illustration, large airflow arrows note that the cool air inlet faces perpendicular to the in-line stovepipe installation while the hot air outlet directs hot air downwards. In the spirit of the invention, the respective configurations of the inlet and outlet benefit by drawing cooler air from the back of the stove while forcing hot air down and into the living space, as further described below.

Connecting the cool air inlet to the hot air outlet is an air channel (5). The air channel is sized and configured to optimize heat transfer to a heat dissipation fin assembly (6) sandwiched between an inside wall (5A) and an outside wall (5B). The heat dissipation fin assembly optimizes heat transfer by convection and conduction from the inside wall to the air channel as is well known in the art. In the spirit of the invention, the heat dissipation fin assembly is configured to allow maximum air flow across the greatest surface area as possible. Also known in the art, the fin assembly touches or attaches to the inside wall, conducting heat directly, and not touching the outside wall allowing the airflow to absorb maximum amounts of latent heat from the appliance while minimizing the conduction of heat to the outside wall.

Continuing with the illustration, a blower fan (7) draws cool air through the cool air inlet (3) across a thermal electric generator (8). Well known in the art, the thermal electric generator is based on the seebeck principles using typically a P-N nodal solid-state array. The thermal electric generator is positioned on a on a heat-sink/insulator, optimizing heat flow to the hot side of the thermal electric generator. A power wire (9) feeds the electrical current from the back of thermal electric generator to the blower fan. The blower fan and power wire are sufficiently positioned away from the inside wall (5A) further down the throat of the cool air inlet to meet maximum heat allowances as is well known in the art. Also well known in the art, the blower fan (7) may be installed on insulated struts further protecting it from conductive heat.

In the preferred embodiment of the invention, once the hot gas venting apparatus starts, the thermal electric generator senses a heat-gradient between the inside wall and the air channel ambient air temperature. The initial gradient starts the blower fan, thus increasing the gradient more by delivering cool air across the cool side of the thermal electric generator.

In another preferred embodiment of the invention, the cool air passes over the thermal electric generator, thus producing a greater and greater heat-gradient, producing a greater and greater current flow to the blower fan thus producing a faster fan speed. As the gas venting appliance continues to reach a sustained operational temperature, the invention reaches a steady state of continuous operation, moving cool inside room air across the thermal electric generator and further across the heat dissipation fin assembly pushing freshly warmed air out the hot air outlet to the room.

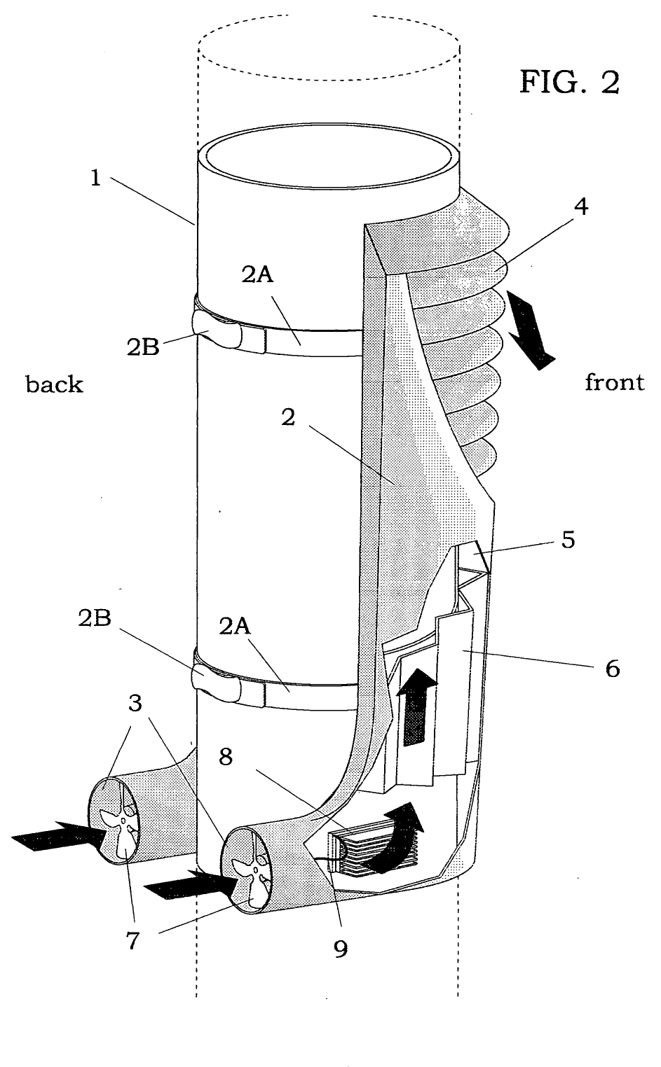

Turning to the illustration of FIG. 2, an alternate embodiment of the invention shows the invention as an attachment to an existing installed hot gas vent pipe. In the spirit of the invention, the back side of the invention has been closed and reconfigured to slip over the conventional stovepipe. In this configuration, the sizing of the invention along which the invention rests against a length an existing stovepipe (1) is not critical as in the retrofit installation described above. This configuration of the invention allows for free placement along an existing stovepipe.

Holding the invention to the existing stovepipe are two straps (2A) positioned sufficiently apart to secure the invention. In this embodiment, a buckle (2B) on each strap cinches it tightly round the existing stovepipe. Dual air inlets (3) are positioned on either side of the invention sufficiently open at the ends and away from the existing stovepipe to draw in cool room air. The air inlets are further configured to slip past either side of the existing stovepipe for easy installation. In this configuration, the body (2) has two inlets and one hot air outlet (4). It is the intention of this inventor to configure the invention in a symmetric fashion, but those in the art may prefer a single payer inlet on one side because a single configuration suffices and saves expense.

As described above, the body contains an air channel (5), an inside wall (5A), an outside wall (5B), a heat dissipation fin assembly (6), blower fans (7) each with aligned thermal electric generator (8) and connecting power wires (9).

This alternate embodiment of the invention provides a convenient way to slip on the invention to an existing installed hot gas vent pipe such as on a wood or pellet stove pipe. As described above, this embodiment functions the same, though the air flow is redirected through the reconfigured air channel.

In another embodiment of the invention, the self- powered blower fan is incorporated into a heating device or machinery, venting hot air to better circulate air flow within the heating device or machinery and to optimize energy use and conductive heat transfer to a living area.

Although the invention has been described in conjunction with specific embodiments, it is evident that many alternatives and variations will be apparent to those skilled in the art and in light of the foregoing description. Accordingly, the invention is intended to embrace all of the alternatives and variations that fall within the spirit and scope of the appended claims.

What is claimed is:

1. A heat generating device, comprising a body,
an inside wall and an outside wall cylindrically formed about each other, with an air channel between, said walls further formed together and closed at the top and bottom with,
a male pipe connecting flange at said top,
a female pipe connecting flange at said bottom whereas said male flange and said female flange are configured to connect inline with a typical vent pipe,
a cool air inlet near said bottom opening about perpendicular to said female flange and a hot air outlet opening about perpendicular to said male flange,
a heat dissipation fin assembly configured in said air channel whereas formed to draw heat from said inside wall,
a blower fan positioned near said cool air inlet configured to pull cool air into said air channel, a solid-state thermal electric generator positioned between said blower fan and said inner wall,
a connecting power wire from said thermal electric generator to said blower fan,
whereas said vent pipe warms producing a heat-gradient across said thermal electric generator from said inner wall to said air channel producing current to said blower fan by way of said power wire forcing air through enclosed said air channel and warming air across said heat dissipation fin assembly and exiting warm air to a work or living space from said hot air outlet.

2. The heat generating device of claim 1 wherein said inside and outside walls are formed together in a half cylinder along an axis center to said inside wall and closed comprising,
a dual set of straps and buckles securing said body to said vent pipe, a dual set of cool air inlets each formed at opposite bottom sides of said walls,
a dual set of thermal electric generators each positioned respectively between said blower fans and said inside wall and respectively
connected together with,
a dual set of power wires,
whereas said body is freely placed and secured along a random length of said stovepipe with said dual straps and respective buckles and said dual blower fans and said dual thermal electric generators operate respectively together to blow cool air across said heat dissipation fin assembly and exiting warm air to a work or living space from said hot air outlet.

3. The heat generating device of claim 2 wherein one said cool air inlet and respective one said blower fan and respective one thermal electric generator and respective one power wire is removed and said inside and said outside wall are closed between in place of said one removed cool air inlet.
